(19) United States
(12) Patent Application Publication
(10) Pub. No.: US 2025/0102596 A1
(43) Pub. Date: Mar. 27, 2025

(54) SHORT CIRCUIT DETECTION IN A POWER TOOL

(71) Applicant: MILWAUKEE ELECTRIC TOOL CORPORATION, Brookfield, WI (US)

(72) Inventors: Thomas Goltz, Hartford, WI (US); Ankit Chadha, Woodridge, IL (US); Nandini Ganesan, Milwaukee, WI (US); Matthew C. Noel, Fond du Lac, WI (US); Mustafa Ibrahim Abed Al Musawi, Chicago, IL (US); David J. Kitzerow, Chicago, IL (US)

(21) Appl. No.: 18/888,934

(22) Filed: Sep. 18, 2024

Related U.S. Application Data
(60) Provisional application No. 63/584,706, filed on Sep. 22, 2023.

(51) Int. Cl. G01R 31/52; G01R 31/34; G01R 31/56; H02J 7/00; H02K 29/08

(52) U.S. Cl. CPC G01R 31/52; G01R 31/34; G01R 31/56; H02J 7/0063; H02J 7/007182; H02K 29/08; H02J 2207/20

(57) ABSTRACT

Power tools that include a housing, a motor supported by the housing, an inverter positioned between and electrically connected to a battery pack interface and the motor, a gate driver connected to the inverter, a rotational position detector configured to detect a position of the motor, a controller configured to control the gate driver, and a short circuit detection circuit. The short circuit detection circuit is configured to monitor the current in the inverter, compare the current in the inverter to a first current threshold, determine, in response to the current in the inverter being greater than or equal to the first current threshold, whether the position of the motor is changing based on a signal from the rotational position detector, and control, in response to the position of the motor not changing, a switch of the short circuit detection circuit to disable the gate driver.

### RELATED APPLICATIONS

This application claims the benefit of U.S. Provisional Patent Application No. 63/584,706, filed Sep. 22, 2023, the entire content of which is hereby incorporated by reference.

### FIELD

Embodiments described herein relate to short circuit detection and short circuit protection for a power tool.

### SUMMARY

Power tools include circuitry configured to control a motor of the power tool. To prevent damage to the motor and power electronics and expand the lifetime of the power tool, circuitry to detect and prevent harmful conditions, such as short-circuits, can be incorporated into the power tool.

Power tools described herein include a housing, a motor supported by the housing, a battery pack interface configured to receive a battery pack, the battery pack including a plurality of battery cells, an inverter positioned between and electrically connected to the battery pack interface and the motor, a gate driver connected to the inverter, the gate driver configured to control a current in the inverter, a rotational position detector configured to detect a position of the motor, a controller configured to control the gate driver, and a short circuit detection circuit. The short circuit detection circuit is configured to monitor the current in the inverter, compare the current in the inverter to a first current threshold, determine, in response to the current in the inverter being greater than or equal to the first current threshold, whether a position of the motor is changing based on a signal from the rotational position detector, and control, in response to the position of the motor not changing, a switch of the short circuit detection circuit to disable the gate driver.

In some aspects, the power tool includes an indicator configured to provide an indication of a status of the short circuit detection circuit.

In some aspects, the rotational position detector includes a plurality of Hall effect sensors, each Hall effect sensor configured to provide a Hall effect sensor signal corresponding to a position of a rotor of the motor.

In some aspects, the short circuit detection circuit is further configured to select the first current threshold based on a voltage provided by the battery pack to the battery pack interface.

In some aspects, the short circuit detection circuit is further configured to adjust a value of the first current threshold based on a change in the current in the inverter.

In some aspects, the short circuit detection circuit is further configured to determine whether an expected braking time has elapsed, compare, in response to the expected braking time having elapsed, the current in the inverter to the first current threshold, and control, in response to the current in the inverter being greater than or equal to the first current threshold and in response to the expected braking time having elapsed, the switch of the short circuit detection circuit to disable the gate driver.

In some aspects, the short circuit detection circuit is further configured to determine, in response to the position of the motor not changing, whether a stall time has elapsed, and control, in response to the stall time having elapsed, the switch of the short circuit detection circuit to disable the gate driver.

In some aspects, the power tool includes a trigger configured to be actuated. The short circuit detection circuit is further configured to detect actuation of the trigger, drive, in response to the actuation of the trigger, the motor, and compare the current in the inverter to a first current threshold and in response to the trigger being released while driving the motor.

In some aspects, the short circuit detection circuit is further configured to enable the gate driver in response to actuation of the trigger and in response to the current in the inverter being less than the first current threshold.

Methods described herein include a method for controlling a power tool. The method includes monitoring, with a short circuit detection circuit, current in an inverter, the inverter positioned between and electrically connected to a battery pack interface and a motor, and comparing, with the short circuit detection circuit, the current in the inverter to a first current threshold. The method includes determining, with the short circuit detection circuit and in response to the current in the inverter being greater than or equal to the first current threshold, whether a position of the motor is changing based on a signal from a rotational position detector, and controlling, with the short circuit detection circuit, in response to the position of the motor not changing, a switch of the short circuit detection circuit to disable a gate driver, wherein the gate driver is configured to control a current in the inverter.

In some aspects, the method includes providing, with an indicator, an indication of a status of the short circuit detection circuit.

In some aspects, the method includes receiving, by the battery pack interface, a battery pack, and selecting the first current threshold based on a voltage provided by the battery pack to the battery pack interface.

In some aspects, the method includes adjusting a value of the first current threshold based on a change in the current in the inverter.

In some aspects, the method includes determining whether an expected braking time has elapsed, comparing, in response to the expected braking time having elapsed, the current in the inverter to the first current threshold, and controlling, in response to the current in the inverter being greater than or equal to the first current threshold and in response to the expected braking time having elapsed, the switch of the short circuit detection circuit to disable the gate circuit.

In some aspects, the method includes determining, in response to the position of the motor not changing, whether a stall time has elapsed, and controlling, in response to the stall time having elapsed, the switch of the short circuit detection circuit to disable the gate driver.

Power tools described herein include a housing, a motor supported by the housing, a battery pack interface configured to receive a battery pack, the battery pack including a plurality of battery cells, an inverter positioned between and electrically connected to the battery pack interface and the motor, a gate driver connected to the inverter, the gate driver configured to control a current in the inverter, a controller configured to control the gate driver, and a short circuit detection circuit. The short circuit detection circuit is configured to monitor the current in the inverter, compare the current in the inverter to a first current threshold, compare, in response to the current in the inverter being greater than or equal to the first current threshold, the current in the inverter to a second current threshold, wherein a value of the second current threshold is based on a timer, increment, in response to the current in the inverter being greater than or equal to the second current threshold, the timer, and control, in response to the timer being greater than or equal to a timer threshold, a switch of the short circuit detection circuit to disable the gate driver.

In some aspects, the short circuit detection circuit is further configured to increment, in response to the increment of the timer, the second current threshold.

In some aspects, the short circuit detection circuit is further configured to compare, in response to the current in the inverter being greater than or equal to the first current threshold, the current in the inverter to the incremented second current threshold, and increment, in response to the current in the inverter being greater than or equal to the incremented second current threshold, the timer.

In some aspects, the power tool includes a rotational position detector configured to detect a position of the motor. The short circuit detection circuit is further configured to determine, in response to the current in the inverter being greater than or equal to the second current threshold, whether the position of the motor is changing based on a signal from the rotational position detector, and increment, in response to the position of the motor not changing, the timer.

In some aspects, the short circuit detection circuit is further configured to determine, in response to the current in the inverter being less than the first current threshold, whether an expected braking time has elapsed, compare, in response to the expected braking time having elapsed, the current in the inverter to the first current threshold, and control, in response to the current in the inverter being greater than or equal to the first current threshold and in response to the expected braking time having elapsed, the switch of the short circuit detection circuit to disable the gate driver.

Before any embodiments are explained in detail, it is to be understood that the embodiments are not limited in application to the details of the configurations and arrangements of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

Other aspects of the embodiments will become apparent by consideration of the detailed description and accompanying drawings.

### BRIEF DESCRIPTION OF THE DRAWINGS

FIG. 1A illustrates a side view of a power tool in accordance with some embodiments.

FIG. 1B illustrates a front view of a power tool in accordance with some embodiments.

FIG. 2 illustrates a block diagram of a control system of a power tool in accordance with some embodiments.

FIG. 3 illustrates a battery pack for use in a power tool in accordance with some embodiments.

FIG. 4 illustrates a block diagram of a control system of a battery pack in accordance with some embodiments.

FIG. 5 illustrates a short circuit detection circuit in accordance with some embodiments.

FIG. 6 illustrates a short circuit threshold in accordance with some embodiments.

FIG. 7 illustrates another short circuit threshold in accordance with some embodiments.

FIG. 8 illustrates a block diagram of a short circuit detection system in accordance with some embodiments.

FIG. 9 illustrates a circuit diagram of an example overcurrent comparator circuit included in the short circuit detection system of FIG. 8.

FIG. 10 illustrates a circuit diagram of an example counter reset circuit included in the short circuit detection system of FIG. 8.

FIG. 11 illustrates a circuit diagram of an example stall shut down circuit included in the short circuit detection system of FIG. 8.

FIG. 12 illustrates a circuit diagram of an example counter delayed overcurrent detection circuit included in the short circuit detection system of FIG. 8.

FIG. 13 illustrates a circuit diagram of an example gate disable circuit included in the short circuit detection system of FIG. 8.

FIG. 14 illustrates a circuit diagram of an example control system of a power tool in accordance with some embodiments.

FIG. 15 illustrates a process for implementing short circuit mitigation in a power tool in accordance with some embodiments.

FIG. 16 illustrates a process for implementing short circuit mitigation in a power tool in accordance with some embodiments.

### DETAILED DESCRIPTION

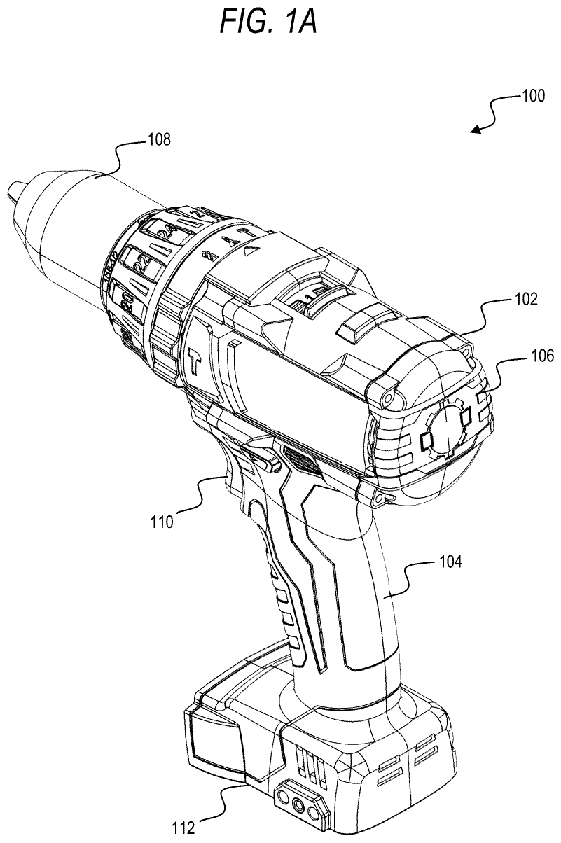

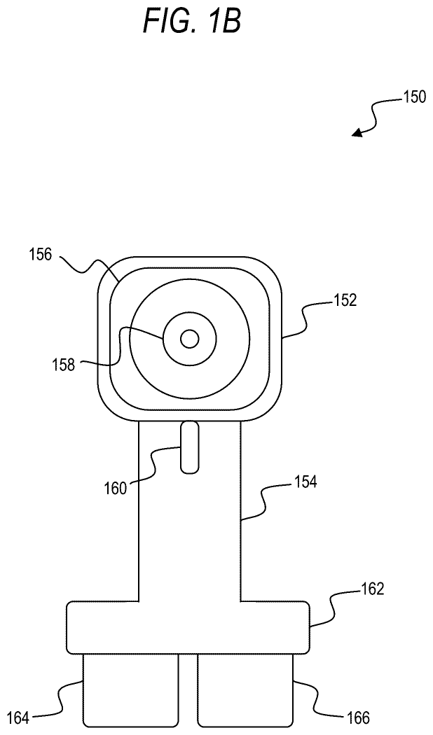

FIG. 1A illustrates a power tool 100 including a brushless direct current (“BLDC”) motor. The power tool 100 is, for example, a brushless hammer drill including a housing 102. The housing 102 includes a handle portion 104 and motor housing portion 106. The power tool 100 further includes an output driver 108 (illustrated as a chuck), trigger 110, and a battery pack interface 112. The battery pack interface 112 is configured to mechanically and electrically connect to a power tool battery pack. Although FIG. 1A illustrates a hammer drill, in some embodiments, the components described herein are incorporated into other types of power tools including drill-drivers, impact drivers, impact wrenches, angle grinders, circular saws, reciprocating saws, string trimmers, leaf blowers, vacuums, and the like. In a brushless motor power tool, such as power tool 100, switching elements are selectively enabled and disabled by control signals from a controller to selectively apply power from a power source (e.g., battery pack) to drive a brushless motor.

FIG. 1B illustrates a power tool 150 including a BLDC motor. The power tool 150 is, for example, a brushless hammer drill including a housing 152. The housing 152 includes a handle portion 154 and motor housing portion 156. The power tool 150 further includes an output driver 158 (illustrated as a chuck), a trigger 160, and a battery pack interface 162. The battery pack interface 162 is configured to receive a plurality of battery packs, such as battery pack 164 and battery pack 166. Although FIG. 1B illustrates a hammer drill, in some embodiments, the components described herein are incorporated into other types of power tools including drill-drivers, impact drivers, impact wrenches, angle grinders, circular saws, reciprocating saws, string trimmers, leaf blowers, vacuums, and the like.

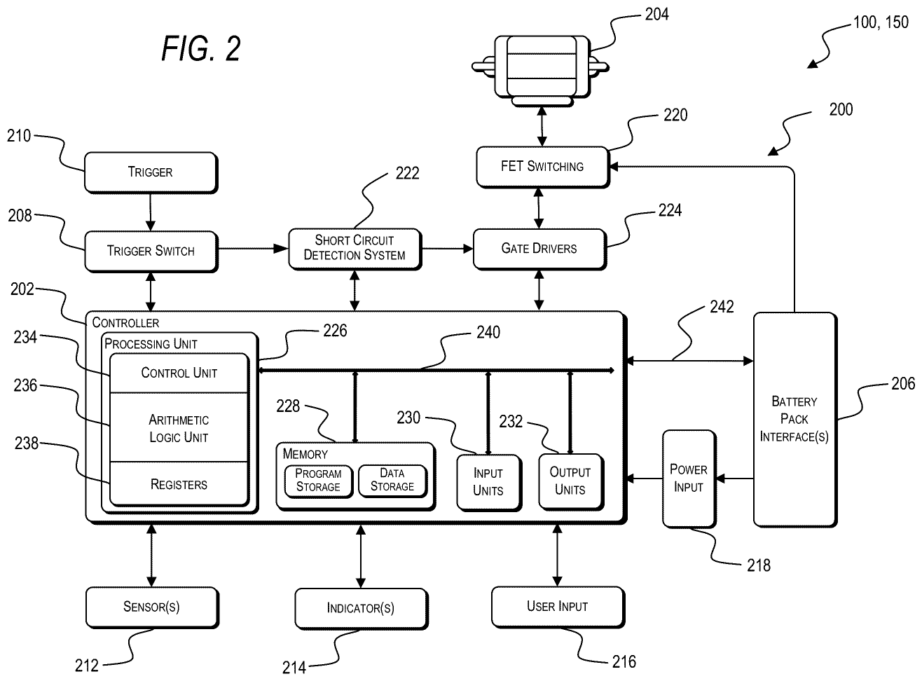

FIG. 2 illustrates a control system 200 for the power tool 100, 150 that includes a short circuit detection system. The control system 200 includes a controller 202. The controller 202 is electrically and/or communicatively connected to a variety of modules or components of the power tool 100, 150. For example, the illustrated controller 202 is electrically connected to a motor 204, a battery pack interface 206, a trigger switch 208 (connected to a trigger 210), one or more sensors 212 (also referred to as sensing circuits), one or more indicators 214, a user input module 216, a power input module 218, an inverter or a FET switching module 220 (e.g., including a plurality of switching FETs), and gate drivers 224 for driving the FET switching module 220. The controller 202 includes combinations of hardware and software that are operable to, among other things, control the operation of the power tool 100, 150, monitor the operation of the power tool 100, 150, activate the one or more indicators 214 (e.g., an LED), etc. A short circuit detection system or circuit 222 is connected to the controller 202 and the gate drivers 224. In some embodiments, the sensors 212 measure or detect a current in the inverter or FET switching module 220 (e.g., a current of one or more phases of the inverter).

The controller 202 includes a plurality of electrical and electronic components that provide power, operational control, and protection to the components and modules within the controller 202 and/or the power tool 100, 150. For example, the controller 202 includes, among other things, a processing unit 226 (e.g., a microprocessor, a microcontroller, an electronic controller, an electronic processor, or another suitable programmable device), a memory 228, input units 230, and output units 232. The processing unit 226 includes, among other things, a control unit 234, an arithmetic logic unit (“ALU”) 236, and a plurality of registers 238, and is implemented using a known computer architecture (e.g., a modified Harvard architecture, a von Neumann architecture, etc.). The processing unit 226, the memory 228, the input units 230, and the output units 232, as well as the various modules or circuits connected to the controller 202 are connected by one or more control and/or data buses (e.g., common bus 240). The control and/or data buses are shown generally in FIG. 2 for illustrative purposes. The use of one or more control and/or data buses for the interconnection between and communication among the various modules, circuits, and components would be known to a person skilled in the art in view of the embodiments described herein.

The memory 228 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 226 is connected to the memory 228 and executes software instructions that are capable of being stored in a RAM of the memory 228 (e.g., during execution), a ROM of the memory 228 (e.g., on a generally permanent basis), or another non-transitory computer readable medium such as another memory or a disc. Software included in the implementation of the power tool 100, 150 can be stored in the memory 228 of the controller 400. The software includes, for example, firmware, one or more applications, program data, filters, rules, one or more program modules, and other executable instructions. The controller 202 is configured to retrieve from the memory 228 and execute, among other things, instructions related to the control processes and methods described herein. In other constructions, the controller 202 includes additional, fewer, or different components.

The battery pack interface 206 includes a combination of mechanical components (e.g., rails, grooves, latches, etc.) and electrical components (e.g., one or more terminals) configured to and operable for interfacing (e.g., mechanically, electrically, and communicatively connecting) with a battery pack. For example, power provided by the battery pack 164, 166, 300 to the power tool 100, 150 is provided through the battery pack interface 206 to the power input module 218. The power input module 218 includes combinations of active and passive components to regulate or control the power received from the battery pack 164, 166, 300 prior to power being provided to the controller 202. The battery pack interface 206 also supplies power to the FET switching module 220 to be switched by the switching FETs to selectively provide power to the motor 204. The battery pack interface 206 also includes, for example, a communication line 242 for providing a communication line or link between the controller 202 and the battery pack 164, 166, 300. In some embodiments, the controller 202 is also electrically and/or communicatively connected to the short circuit detection circuit 222 via a signal line.

The sensors 212 include one or more current sensors, one or more speed sensors, one or more Hall Effect sensors, one or more temperature sensors, etc. The indicators 214 include, for example, one or more light-emitting diodes (“LEDs”). The indicators 214 can be configured to display conditions of, or information associated with, the power tool 100, 150. For example, the indicators 214 are configured to indicate measured electrical characteristics of the power tool 100, 150, the status of the power tool, the status of the short circuit detection circuit 222, etc. The user input module 216 is operably coupled to the controller 202 to, for example, select a forward mode of operation or a reverse mode of operation, a torque and/or speed setting for the power tool 100, 150 (e.g., using torque and/or speed switches), etc. In some embodiments, the user input module 216 includes a combination of digital and analog input or output devices required to achieve a desired level of operation for the power tool 100, 150, such as one or more knobs, one or more dials, one or more switches, one or more buttons, etc.

The short circuit detection circuit 222 is configured to monitor one or more electrical characteristics of the power tool 100, 150 for conditions that indicate a short circuit fault condition. In some embodiments, for example, the short circuit detection circuit 222 monitors one or more electrical characteristics of the plurality of switching FETs of the FET switching module 220 for conditions indicating shoot-though. In some embodiments, for example, the short circuit detection circuit 222 monitors one or more electrical characteristics of motor 204 for conditions indicating a locked rotor. In some embodiments, when the short circuit detection circuit 222 determines that one or more electrical characteristics indicate a short circuit fault condition, the short circuit detection circuit 222 commands the gate drivers 224 to prevent the FET switching module 220 from providing power to the motor 204. In some embodiments, short circuit detection circuit 222 determines that one or more electrical characteristics indicate an unwanted current, an uncontrolled current, a damaging current, a hazardous current, and the like.

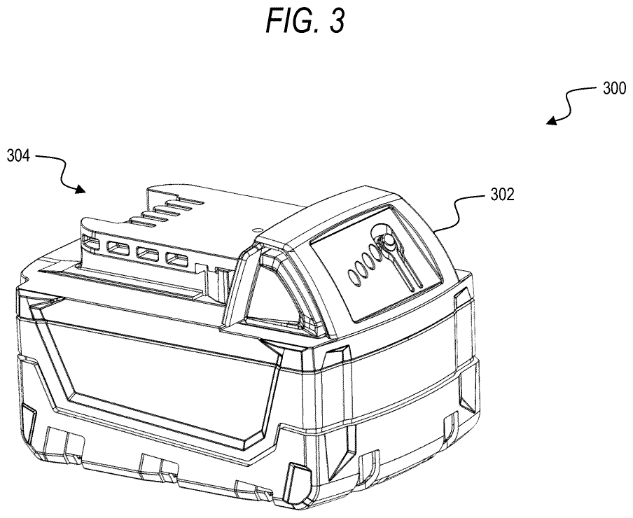

FIG. 3 illustrates a battery pack 300. The battery pack 300 includes a housing 302 and an interface portion 304 for connecting the battery pack 300 to a power tool, such as the power tool 100, 150. In some embodiments, the battery pack 300 has a nominal voltage rating of 18 Volts.

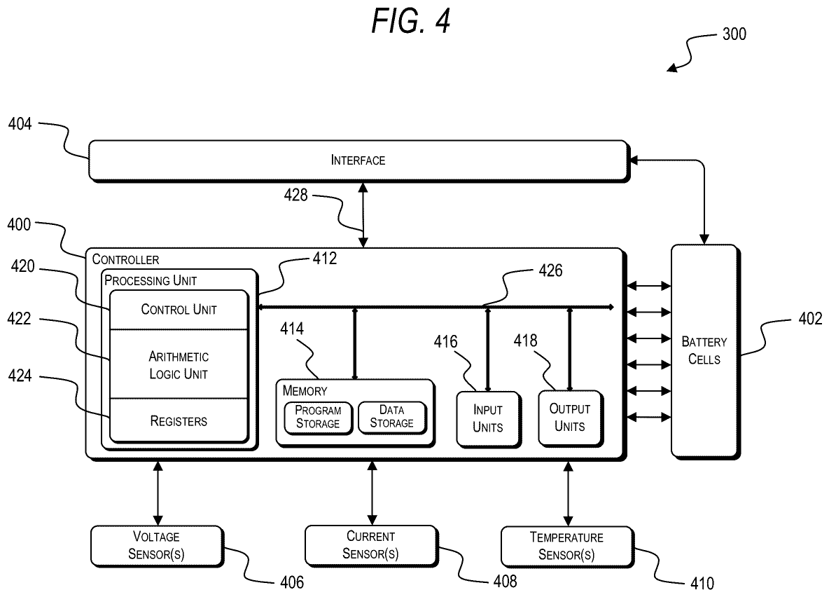

FIG. 4 illustrates a control system for the battery pack 300. The control system includes a controller 400. The controller 400 is electrically and/or communicatively connected to a variety of modules or components of the battery pack 300. For example, the illustrated controller 400 is connected to one or more battery cells 402 and an interface 404 (e.g., the interface portion 304 of the battery pack 300 illustrated in FIG. 3). The controller 400 is also connected to one or more voltage sensors or voltage sensing circuits 406, one or more current sensors or current sensing circuits 408, and one or more temperature sensors or temperature sensing circuits 410. The controller 400 includes combinations of hardware and software that are operable to, among other things, control the operation of the battery pack 300, monitor a condition of the battery pack 300, enable or disable charging of the battery pack 300, enable or disable discharging of the battery pack 300, etc.

The controller 400 includes a plurality of electrical and electronic components that provide power, operational control, and protection to the components and modules within the controller 400 and/or the battery pack 300. For example, the controller 400 includes, among other things, a processing unit 412 (e.g., a microprocessor, a microcontroller, an electronic processor, an electronic controller, or another suitable programmable device), a memory 414, input units 416, and output units 418. The processing unit 412 includes, among other things, a control unit 420, an ALU 422, and a plurality of registers 424, and is implemented using a known computer architecture (e.g., a modified Harvard architecture, a von Neumann architecture, etc.). The processing unit 412, the memory 414, the input units 416, and the output units 418, as well as the various modules or circuits connected to the controller 400 are connected by one or more control and/or data buses (e.g., common bus 426). The control and/or data buses are shown generally in FIG. 4 for illustrative purposes. The use of one or more control and/or data buses for the interconnection between and communication among the various modules, circuits, and components would be known to a person skilled in the art in view of the invention described herein.

The memory 414 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 412 is connected to the memory 414 and executes software instructions that are capable of being stored in a RAM of the memory 414 (e.g., during execution), a ROM of the memory 414 (e.g., on a generally permanent basis), or another non-transitory computer readable medium such as another memory or a disc. Software included in the implementation of the battery pack 300 can be stored in the memory 414 of the controller 400. The software includes, for example, firmware, one or more applications, program data, filters, rules, one or more program modules, and other executable instructions. The controller 400 is configured to retrieve from the memory 414 and execute, among other things, instructions related to the control processes and methods described herein. In other constructions, the controller 400 includes additional, fewer, or different components.

The interface 404 includes a combination of mechanical components (e.g., rails, grooves, latches, etc.) and electrical components (e.g., one or more terminals) configured to and operable for interfacing (e.g., mechanically, electrically, and communicatively connecting) the battery pack 300 with another device (e.g., a power tool, a battery pack charger, etc.). For example, the interface 404 is configured to communicatively connect to the controller 400 via a communications line 428.

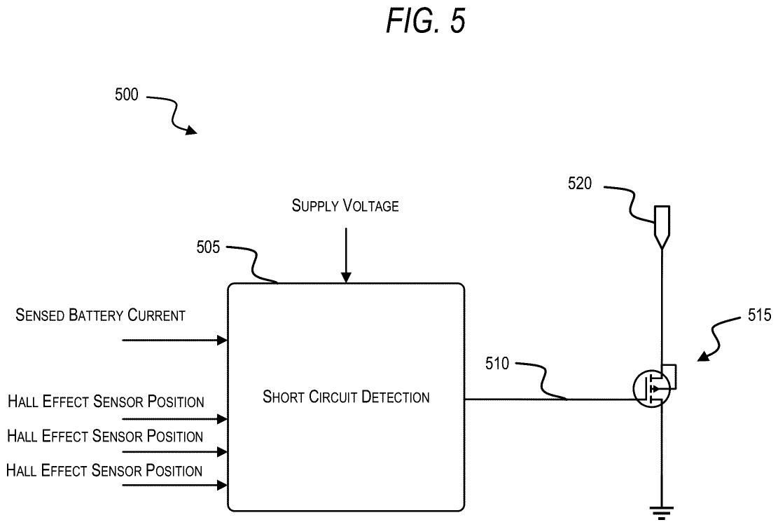

FIG. 5 illustrates an embodiment of a short circuit detection circuit 500. The short circuit detection circuit 500 includes a programmable integrated circuit 505 that is configured to monitor for a short circuit condition of the power tool 100, 150. The circuit 505 (e.g., short circuit detection system 222) is powered by a supply voltage (e.g., 3.3V, 5V, etc.). The circuit 505 receives an input voltage signal related to a sensed battery pack current. The circuit 505 also receives one or more Hall effect sensor signals (e.g., Phase A Position, Phase B position, Phase C Position, etc.). The one or more input Hall effect sensor signals correspond to the position of a rotor of the motor 204. The one or more input Hall sensor signals may be used by the circuit 505 to determine the current flowing through the motor 204. If the circuit 505 detects a short circuit condition, the circuit 505 provides an output 510 to a switch 515 to disable the motor 204 (e.g., disable a gate driver that drives the switch 515). Although only one switch is illustrated, a plurality of switches (e.g., in the inverter or FET switching module 220) are similarly controlled to disable the motor 204. Power 520 from the battery pack is then prevented from driving the motor 204.

The circuit 505 is programmed to include a plurality of different short circuit overcurrent thresholds. In some embodiments, a particular short circuit overcurrent threshold is selected for a particular power tool application (e.g., based on platform voltage). In some embodiments, the circuit 505 is configured to dynamically adjust the short circuit overcurrent threshold based on a voltage associated with the power tool, such as a battery pack voltage or a DC link bus voltage. The higher the voltage value, the higher the short circuit overcurrent threshold can be set. For example, larger battery packs including higher voltages and capacities can have lower direct current internal resistances than other battery packs. The short circuit overcurrent threshold can be increased for such battery packs that are capable of outputting higher currents. In other embodiments, the circuit 505 is configured to dynamically adjust the short circuit overcurrent threshold based on the value of the current over time.

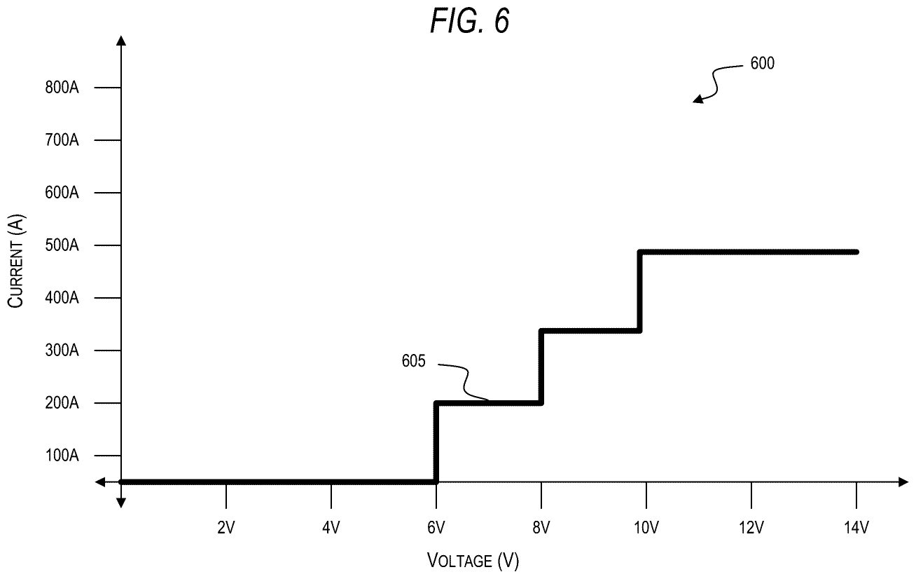

FIG. 6 illustrates a graph 600 of the short circuit overcurrent threshold according to some embodiments. The values illustrated in FIG. 6 are merely exemplary and provided for descriptive purposes. Different threshold values could be used for different power tool applications. As the voltage related to the battery pack or DC link voltage increases, the short circuit overcurrent threshold 605 also increases. In some embodiments, the short circuit overcurrent threshold 605 is based on a voltage of one or more battery packs connected to the power tool 100, 150. The short circuit overcurrent threshold 605 can be modified as the one or more battery packs become depleted. In other embodiments, the short circuit overcurrent threshold 605 is based on a DC link bus voltage (e.g., where multiple battery packs may be attached to the power tool 100, 150). The area under the short circuit overcurrent threshold 605 corresponds to the operating range of the power tool 100, 150. In some embodiments, rather than the short circuit overcurrent threshold being only a current value that is used to disable a motor when exceeded, a temporal aspect of the short circuit overcurrent threshold can be implemented. For example, the short circuit overcurrent threshold need to be exceeded for a period of time before the motor is disabled. By incorporating time as a condition for disabling the motor, different time thresholds can be set. For example, relatively higher current values can be permitted for smaller periods of time, and relatively lower current values can be permitted for longer periods of time. Configuring the short circuit overcurrent thresholds in such a way provides greater flexibility to extract as much power from the battery pack(s) as possible.

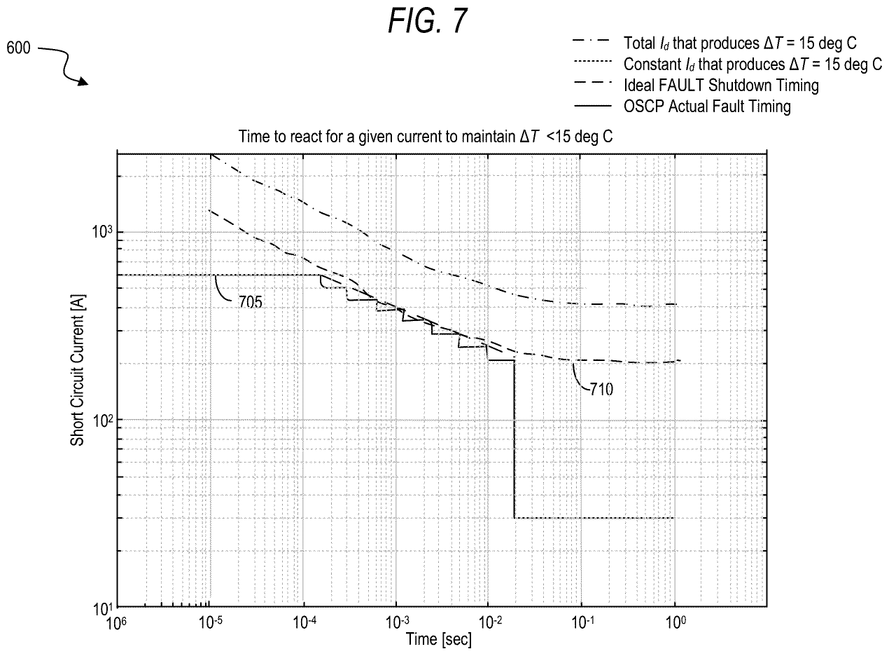

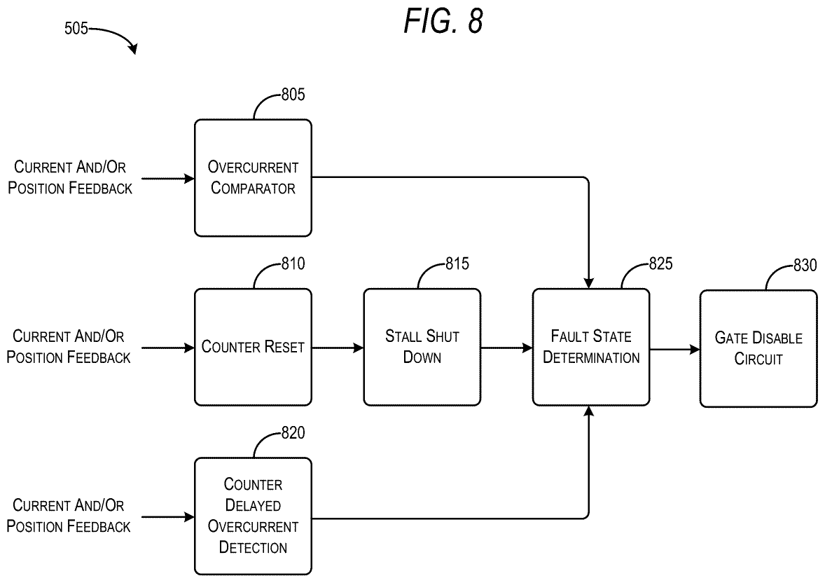

FIG. 7 illustrates a graph 700 of the short circuit overcurrent threshold. The values illustrated in FIG. 8 are merely exemplary and provided for descriptive purposes. Different threshold values could be used for different power tool applications. The graph 700 provides a stepped short circuit overcurrent threshold 705 that decreases over time. The stepped short circuit overcurrent threshold 705 may be based on a measured current value 710 that maintains a change in temperature (for example, the motor temperature, gate driver temperature, FET switching temperature, etc.) below a threshold (for example, 15° C.). The stepped short circuit overcurrent threshold 705 provides for a greater current during initial startup of the power tool 100, 150.

FIG. 8 illustrates a block diagram of example circuits that form the programmable integrated circuit 505 (e.g., short circuit detection system 222). The programmable integrated circuit 505 includes an overcurrent comparator 805, a counter reset circuit 810, a stall shut down circuit 815, a counter delayed overcurrent detection circuit 820, a fault state determination circuit 825, and a gate disable circuit 830.

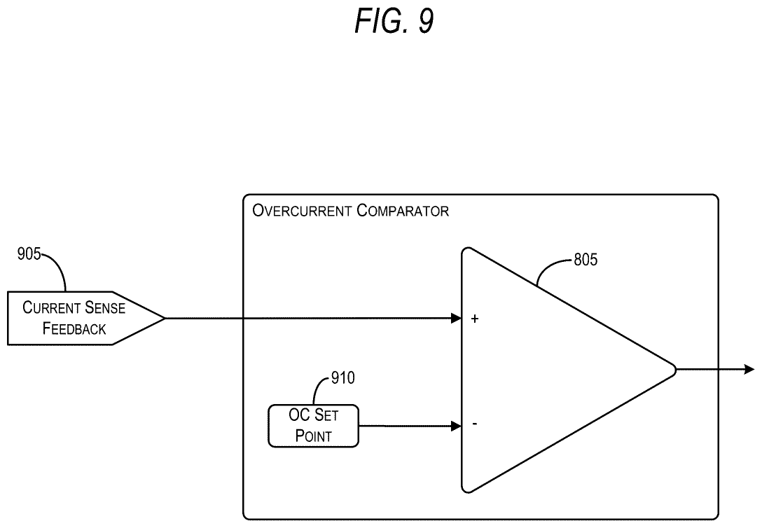

FIG. 9 illustrates an example of the overcurrent comparator 805. The overcurrent comparator 805 receives a current signal 905 indicative of a current through the motor 204 and receives an overcurrent set point 910 as input. The overcurrent comparator 805 sets the maximum current value that can pass through the FET switching module 220. While FIG. 9 illustrates the overcurrent comparator 805 in terms of hardware, the same functionality can be implemented in software without requiring this exact configuration of hardware.

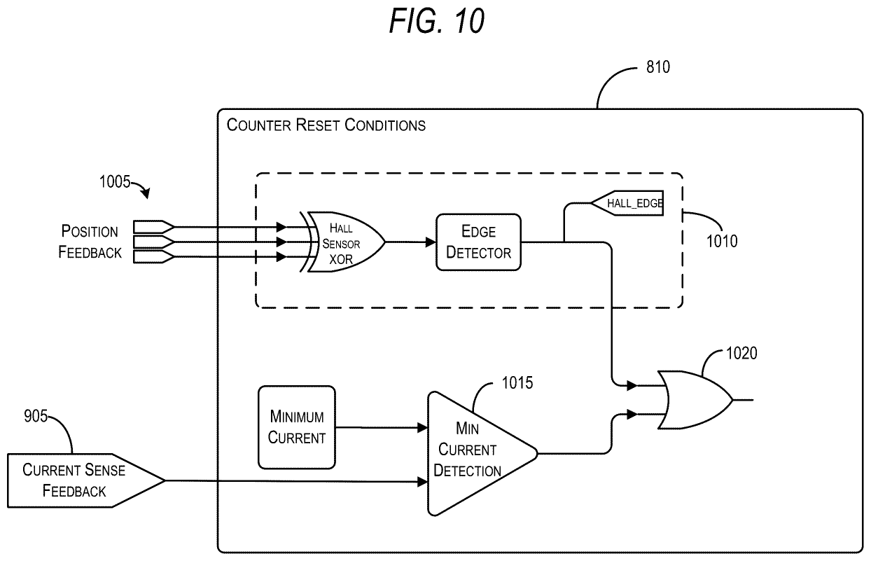

FIG. 10 illustrates an example of the counter reset circuit 810. The counter reset circuit 810 receives the current signal 905 and Hall effect sensor inputs 1005 as inputs. The counter reset circuit 810 includes a Hall effect state reset circuit 1010 that receives the Hall effect sensor inputs 1005 and resets all counters during Hall state transitions (e.g., motor phase transitions), as Hall state transitions indicate that the motor 204 is spinning and properly operating. The counter reset circuit 810 includes a minimum current detection comparator 1015 that receives the current signal 905. The minimum current detection comparator 1015 compares the current signal 905 to a minimum current value. The current signal 905 must continually remain above the minimum current value to trigger a fault. Zero states of the current signal 905 (resulting from freewheeling from the FET switching module 220) reset the counter. The counter reset circuit 810 includes an OR gate 1020 that receives the outputs from the Hall effect state reset circuit 1010 and the minimum current detection comparator 1015. Counters are reset on either Hall effect state transition or “zero states” of the current signal 905. While FIG. 10 illustrates the counter reset circuit 810 in terms of hardware, the same functionality can be implemented in software without requiring this exact configuration of hardware.

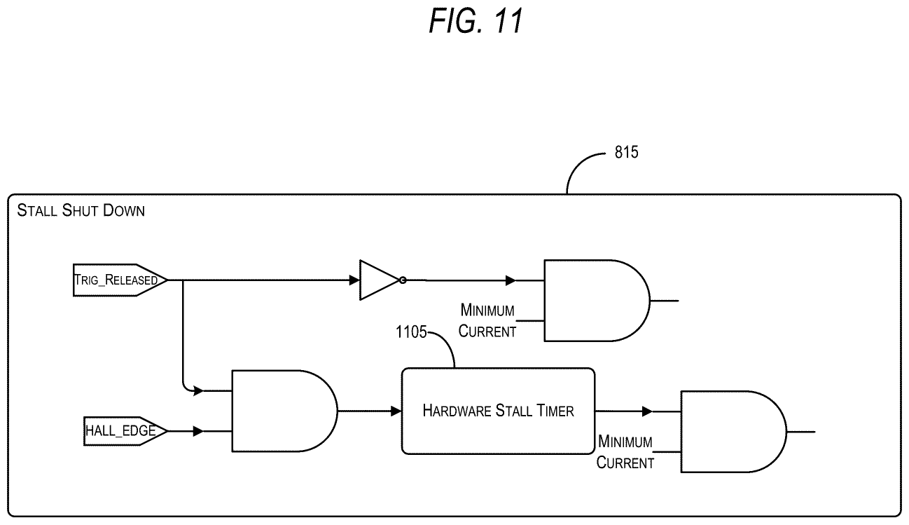

FIG. 11 illustrates an example of the stall shut down circuit 815. The stall shut down circuit 815 receives the output from the minimum current detection comparator 1015. When the motor 204 is fully braked, if the stall shut down circuit 815 detects that a current is still present (based on the output of the minimum current detection comparator 1015), a fault is flagged.

The stall shut down circuit 815 includes a hardware stall timer 1105 that has a first output (for example, a HIGH output) when both the time since the last signal from the edge hall sensor is greater than or equal to a stall counter, and when the time since the last signal from the edge Hall effect sensor is less than a stall timer check window. The hardware stall timer 1105 has a second output (for example, a LOW output) when either the time since the last signal from the edge Hall effect sensor is less than the stall counter, and when the time since the last signal from the edge Hall effect sensor is greater than the stall timer check window.

The stall shut down circuit 815 resets every time a Hall effect edge is sensed during a trigger pull, signifying rotation of the motor 204. If the motor 204 does not rotate after the trigger pull and there is a motor current detected after the stall counter has been satisfied, a fault is detected and flagged. While FIG. 11 illustrates the stall shutdown circuit 815 in terms of hardware, the same functionality can be implemented in software without requiring this exact configuration of hardware.

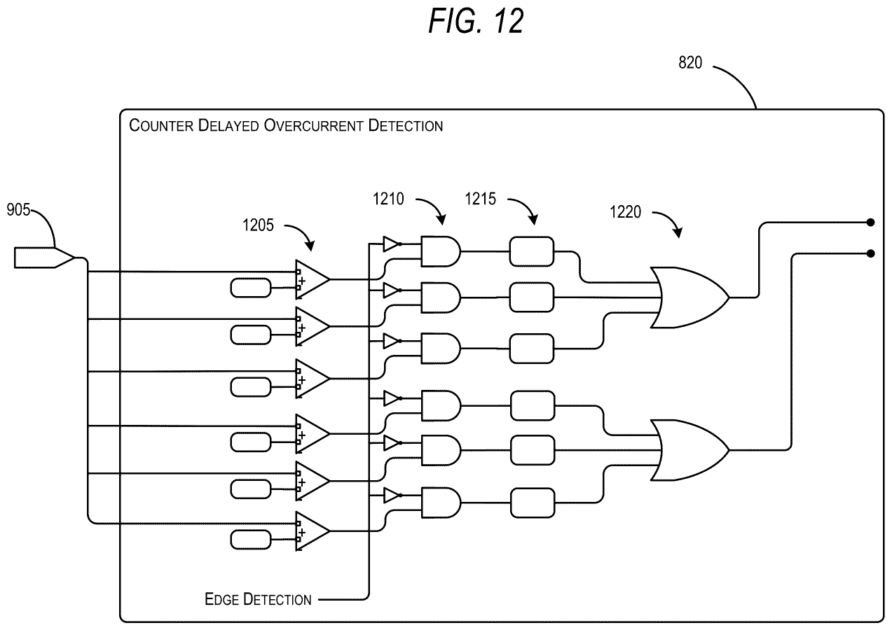

FIG. 12 illustrates an example of the counter delayed overcurrent detection circuit 820. The counter delayed overcurrent detection circuit 820 includes, for example, a plurality of comparators 1205 that receive the current signal 905 and an associated overcurrent set point value. While FIG. 12 illustrates the counter delayed overcurrent detection circuit 820 in terms of hardware, the same functionality can be implemented in software without requiring this exact configuration of hardware. The overcurrent set point values and their timing allowances are given by the transient thermal impedance of the inverters included in the FET switching module 220 and the power produced by a current pulse of a fault event. Timing constraints are set by a pre-defined admitted temperature rise in the inverter FETs during the fault event.

The counter delayed overcurrent detection circuit 820 also includes a plurality of AND gates 1210. The plurality of AND gates 1210 perform an AND operation with the output of respective comparators 1205 and the NOT of the counter reset condition from the counter reset circuit 810. If the output of the counter reset circuit 810 is 0, the output of the AND gates 1210 will be 1. However, Hall XOR output edges and a zero state of the current signal 905 will cause a 0 input to the AND gates 1210, which resets the plurality of counters 1215. Counters are also reset when the current signal 905 falls below the overcurrent set point value. The counter values from the plurality of counters 1215 are provided to OR gates 1220.

The fault state determination circuit 825 receives the outputs from the overcurrent comparator 805, the stall shut down circuit 815, and the counter delayed overcurrent detection circuit 820 and determines whether a fault state is occurring based on those outputs. In some embodiments, the fault state determination circuit 825 is an OR gate.

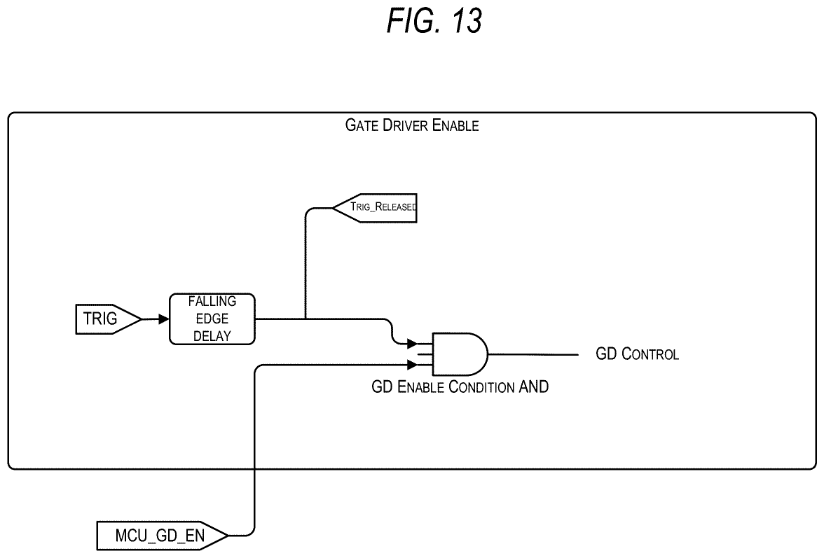

FIG. 13 illustrates an example of the gate disable circuit 830. The gate disable circuit 830 enables or disables the gate drivers 224 based on the fault state. In some embodiments, the gate drivers 224 are enabled when all of the following conditions are met: a trigger signal is present (e.g., the trigger 210 is actuated), a fault is not detected, and the controller 202 is providing a gate enable signal. If any of the conditions are not met, the gate drivers 224 are disabled. The gate enablement is controlled by open drain output of MOSFET 1305. While FIG. 13 illustrates the gate disable circuit 830 in terms of hardware, the same functionality can be implemented in software without requiring this exact configuration of hardware.

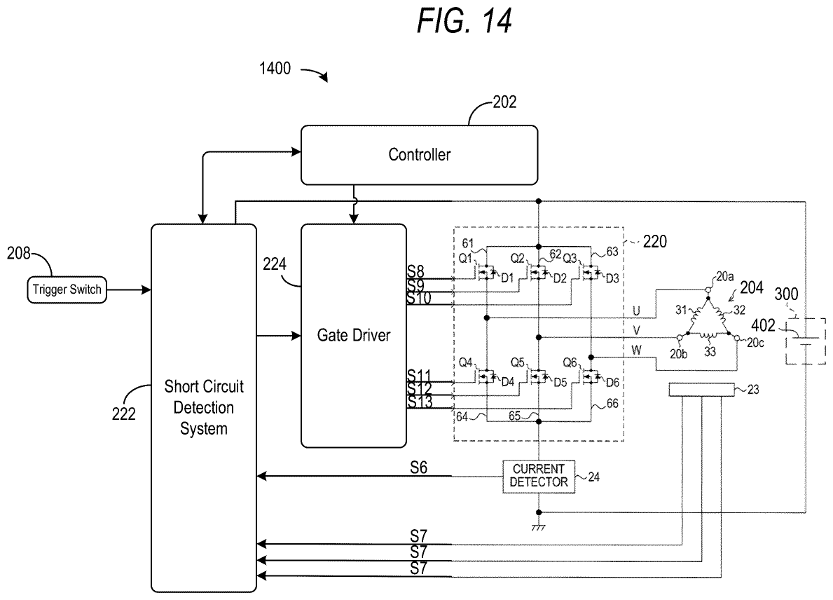

FIG. 14 illustrates a circuit diagram of a control system 1400 for the power tool 100, 150. As shown in FIG. 14, the controller 202 is connected to the gate drivers 224 and the short circuit detection system 222. The controller 202 transmits gate signals to the gate drivers 224 to control the gate drivers 224. The controller 202 transmits fault clear signals to the short circuit detection system 222 if the controller 202 does not independently detect any faults. In the example of FIG. 14, the short circuit detection system 222 detects actuation of the trigger switch 10 and controls the gate drivers 224 (e.g., enables, disables, etc.) based on actuation of the trigger switch 10.

The short circuit detection system 222 receives signal S6, a power-supply current detection signal, from the current detector 24. The short circuit detection system 222 also receives signals S7, rotation position signals from a rotational position detector 23 (e.g., Hall effect sensors providing rotor position signals). The gate drivers 224 transmits drive control signals S8-S13 to the FET switching module 220. The rotation position signals S7 may be used to calculate rotational velocity (e.g., rpm) and/or rotational acceleration. Similarly, the power supply current detection signal S6 may be used to calculate a related power-supply current rate of change. The motor 204 of the present embodiment is a three-phase brushless motor. The battery power supplied by the battery pack 300 is converted into three-phase power by the FET switching module 220, and the three-phase power is supplied to the motor 204.

The motor 204 includes three windings 31, 32, and 33. In the present embodiment, these three windings 31, 32, and 33 are delta-connected. However, in other embodiments, connection methods other than the delta-connection may be employed. Additionally, the motor 204 includes three terminals 20a, 20b, and 20c as terminals for power input.

The rotational position detector 23 is configured to output signals corresponding to a rotational position of the motor 204, or specifically rotation position signals corresponding to a rotational position of a rotor of the motor 204. The rotational position detector 23 includes, for example, three Hall effect sensors. The respective Hall effect sensors are arranged around the rotor of the motor 204 at, for example, 120 degree intervals. Signals outputted from the three Hall effect sensors are input to the short circuit detection system 222. The short circuit detection system 222 detects the rotational position and the rotational speed of the motor 20 on the basis of the signals input from the rotational position detector 23, that is, on the basis of the respective signals from the three Hall effect sensors. Rotational acceleration may also be calculated from these signals.

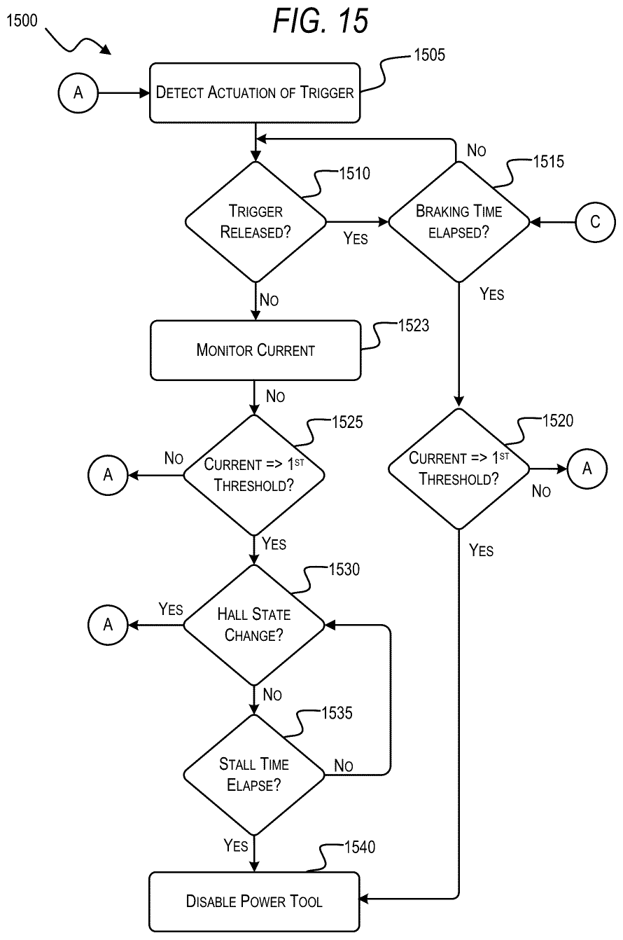

FIG. 15 illustrates a process 1500 for controlling the power tool 100, 150. While the process 1500 is described as being performed by the short circuit detection system 222, in some instances, the process 1500 is performed by a combination of the short circuit detection system 222 and the controller 202. At STEP 1505, the short circuit detection system 222 detects actuation of the trigger 210. At STEP 1510, the short circuit detection system 222 determines whether the trigger 210 is released. When the trigger 210 is released (“YES” at STEP 1510), the short circuit detection system 222 determines whether expected braking time has elapsed (STEP 1515). When the expected braking time has not elapsed (“NO” at STEP 1515), the process 1500 returns to STEP 1510. When the expected braking time has elapsed (“YES” at STEP 1515), the short circuit detection system 222 determines whether the current is greater than or equal to a first current threshold (e.g., a minimum current threshold) (STEP 1520). The short circuit detection system 222 monitors the current through the inverter or FET switching module 220 and motor 204. In some embodiments, the current is monitored by one or more current sensors (e.g., shunt resistors) that detect the current through the motor 204. When the current is not greater than or equal to the first current threshold (“NO” at STEP 1520), the process 1500 returns to STEP 1505. When the current is greater than or equal to the first threshold, the short circuit detection system 222 disables the power tool 100, 150 (STEP 1540). In this instance, a fault has occurred, as current is still present following braking of the motor 204.

Returning to STEP 1510, when the trigger 210 is not released (“NO” at STEP 1510), the short circuit detection system 222 monitors current (STEP 1523) and determines whether the current is greater than or equal to the first threshold (e.g., the minimum current threshold) (STEP 1525). When the current is not greater than or equal to the first threshold (“NO” at STEP 1525), the process 1500 returns to STEP 1505. When the current is greater than or equal to the first threshold (“YES” at STEP 1525), the short circuit detection system 222 determines whether the Hall effect state has changed (STEP 1530). When the Hall effect state has changed (“YES” at STEP 1530), the short circuit detection system 222 returns to STEP 1505. When the Hall effect state has not changed (“NO” at STEP 1530), the short circuit detection system 222 determines whether the stall time has elapsed (STEP 1535). When the stall time has not elapsed (“NO” at STEP 1535) the short circuit detection system 222 returns to STEP 1530. When the stall time has elapsed (“YES” at STEP 1535), the short circuit detection system 222 disables the power tool 100, 150 (STEP 1540) and detects a fault condition. The power tool 100, 150 is disabled by controlling a gate driver for a switch to disable the switch (e.g., in the FET switching module 220) and thereby prevent current from passing to the motor 204.

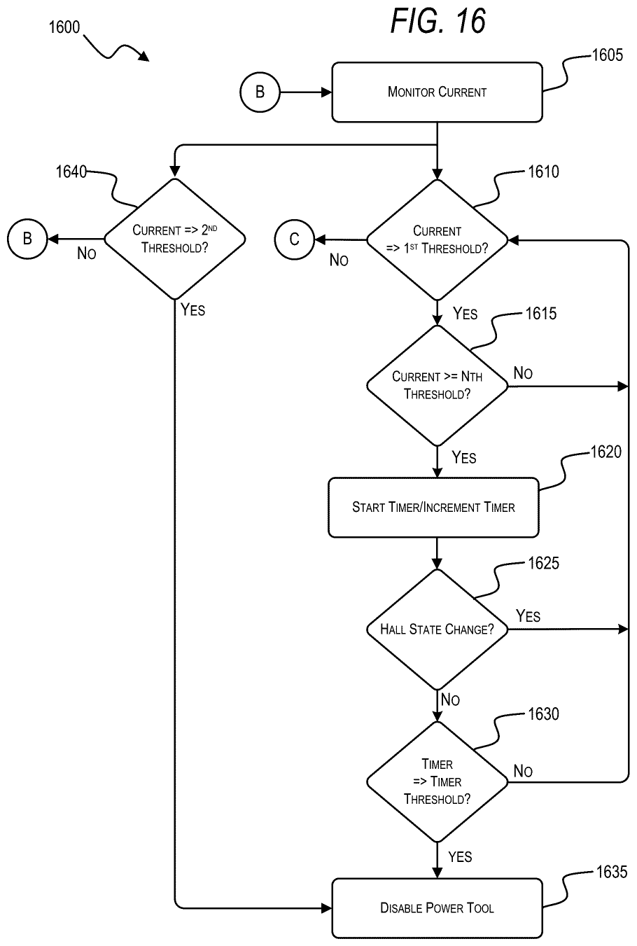

FIG. 16 illustrates a process 1600 for controlling the power tool 100, 150. While the process 1600 is described as being performed by the short circuit detection system 222, in some instances, the process 1600 is performed by a combination of the short circuit detection system 222 and the controller 202. The process 1600 can be implemented in conjunction with the process 1500 such that the two processes are executed in combination and/or in parallel with each other. At STEP 1605, the short circuit detection system 222 monitors a current. The current monitoring of STEP 1605 can be the same current monitoring as STEP 1523. In some embodiments, the short circuit detection system 222 monitors the current through the inverter or FET switching module 220 and motor 204. In some embodiments, the current is monitored by one or more current sensors (e.g., shunt resistors) that detect the current through the motor 204.

At STEP 1610, the short circuit detection system 222 determines whether the current is greater than or equal to a first current threshold (e.g., a minimum current threshold). When the current is less than the first current threshold (“NO” at STEP 1610), the short circuit detection system 222 can return to STEP 1515 of process 1500. When the current is greater than or equal to the first current threshold (“YES” at STEP 1610), the short circuit detection system 222 proceeds to STEP 1615. At STEP 1615, the short circuit detection system 222 determines whether the current is greater than an incremented threshold (e.g., Nth threshold a plurality of thresholds). Particularly, as the timer is incremented, the current threshold is also incremented. When the current is less than the incremented threshold (“NO” at STEP 1615), the short circuit detection system 222 returns to STEP 1610. When the current is greater than or equal to the incremented threshold (“YES” at STEP 1615), the short circuit detection system 222 starts a timer or counter (STEP 1620). The timer or counter is implemented to determine whether the short circuit condition that may be present persists for a period of time (e.g., rather than merely being a transient current spike). In some embodiments, the short circuit detection system 222 includes an internal clock (e.g., a real-time clock) that is used to keep track of time and a separate, dedicated timer or counter is not required. However, for explanatory purposes, the timer is generally described as a way to keep track of elapsed time. After setting the counter, the short circuit detection system 222 proceeds to STEP 1625. At STEP 1625, the short circuit detection system 222 determines whether the Hall effect state has changed. When the Hall effect state has changed (“YES” at STEP 1625), the short circuit detection system 222 returns to STEP 1610. When the Hall effect state has not changed (“NO” at STEP 1625), the short circuit detection system 222 determines whether the timer or counter is greater than or equal to a timer threshold (STEP 1630). When the timer is less than the timer threshold (“NO” at STEP 1630), the short circuit detection system 222 returns to STEP 1610. When the timer is greater than or equal to the timer threshold (“YES” at STEP 1630), the short circuit detection system 222 proceeds to STEP 1635 and disables the power tool 100, 150 and detects a fault condition. The power tool 100, 150 is disabled by controlling a gate driver for a switch to disable the switch (e.g., in the FET switching module 220) and thereby prevent current from passing to the motor 204.

At STEP 1640, the short circuit detection system 222 determines whether the current is greater than or equal to a second current threshold (e.g., a maximum current threshold). When the current is less than the second current threshold (“NO” at STEP 1640), the short circuit detection system 222 returns to STEP 1605 and continues to monitor the current. When the current is greater than or equal to the second current threshold (“YES” at STEP 1640), the short circuit detection system 222 proceeds to STEP 1635 and disables the power tool 100, 150. In this manner, the current is continuously monitored during the STEPS 1625, 1630, 1635.

In some embodiments, if, before the timer reaches the timer threshold, the measured current falls back below the first threshold, the timer is stopped or reset and the power tool 100, 150 continues to operate normally while monitoring the current (at STEP 1605).

Accordingly, embodiments described herein provide a short circuit detection system separate from the primary controller. The short circuit detection system provides for monitoring MOSFET characteristics and monitors for stall states of the motor.

### Representative Features

Representative features are set out in the following clauses, which stand alone or may be combined, in any combination, with one or more features disclosed in the text and/or drawings of the specification.

Clause 1. A power tool comprising: a housing; a motor supported by the housing; a battery pack interface configured to receive a battery pack, the battery pack including a plurality of battery cells; an inverter positioned between and electrically connected to the battery pack interface and the motor; a gate driver connected to the inverter, the gate driver configured to control a current in the inverter; a rotational position detector configured to detect a position of the motor; a controller configured to control the gate driver; and a short circuit detection circuit configured to: monitor the current in the inverter, compare the current in the inverter to a first current threshold, determine, in response to the current in the inverter being greater than or equal to the first current threshold, whether the position of the motor is changing based on a signal from the rotational position detector, and control, in response to the position of the motor not changing, a switch of the short circuit detection circuit to disable the gate driver.

Clause 2: The power tool of clause 1, further comprising: an indicator configured to provide an indication of a status of the short circuit detection circuit.

Clause 3: The power tool of any of the preceding clauses, wherein the rotational position detector includes a plurality of Hall effect sensors, each Hall effect sensor configured to provide a Hall effect sensor signal corresponding to a position of a rotor of the motor.

Clause 4: The power tool of any of the preceding clauses, wherein the short circuit detection circuit is further configured to: select the first current threshold based on a voltage provided by the battery pack to the battery pack interface.

Clause 5: The power tool of any of the preceding clauses, wherein the short circuit detection circuit is further configured to: adjust a value of the first current threshold based on a change in the current in the inverter.

Clause 6: The power tool of any of the preceding clauses, wherein the short circuit detection circuit is further configured to: determine whether an expected braking time has elapsed; compare, in response to the expected braking time having elapsed, the current in the inverter to the first current threshold; and control, in response to the current in the inverter being greater than or equal to the first current threshold and in response to the expected braking time having elapsed, the switch of the short circuit detection circuit to disable the gate driver

Clause 7: The power tool of any of the preceding clauses, wherein the short circuit detection circuit is further configured to: determine, in response to the position of the motor not changing, whether a stall time has elapsed; and control, in response to the stall time having elapsed, the switch of the short circuit detection circuit to disable the gate driver.

Clause 8: The power tool of any of the preceding clauses, further comprising: a trigger configured to be actuated, and wherein the short circuit detection circuit is further configured to: detect actuation of the trigger, drive, in response to actuation of the trigger, the motor, and compare the current in the inverter to a first current threshold in response to the trigger being released while driving the motor.

Clause 9: The power tool of clause 8, wherein the short circuit detection circuit is further configured to: enable the gate driver in response to actuation of the trigger and in response to the current in the inverter being less than the first current threshold.

Clause 10: A method for controlling a power tool, the method comprising: monitoring, with a short circuit detection circuit, current in an inverter, the inverter positioned between and electrically connected to a battery pack interface and a motor; comparing, with the short circuit detection circuit, the current in the inverter to a first current threshold; determining, with the short circuit detection circuit and in response to the current in the inverter being greater than or equal to the first current threshold, whether a position of the motor is changing based on a signal from a rotational position detector; and controlling, with the short circuit detection circuit and in response to the position of the motor not changing, a switch of the short circuit detection circuit to disable a gate driver, wherein the gate driver is configured to control a current in the inverter.

Clause 11: The method of clause 10, further comprising: providing, with an indicator, an indication of a status of the short circuit detection circuit.

Clause 12: The method of any of clauses 10-11, further comprising: receiving, by the battery pack interface, a battery pack; and selecting the first current threshold based on a voltage provided by the battery pack to the battery pack interface.

Clause 13: The method of any of clauses 10-12, further comprising: adjusting a value of the first current threshold based on a change in the current in the inverter.

Clause 14: The method of any of clauses 10-13, further comprising: determining whether an expected braking time has elapsed; comparing, in response to the expected braking time having elapsed, the current in the inverter to the first current threshold; and controlling, in response to the current in the inverter being greater than or equal to the first current threshold and in response to the expected braking time having elapsed, the switch of the short circuit detection circuit to disable the gate driver.

Clause 15: The method of any of clauses 10-14, further comprising: determining, in response to the position of the motor not changing, whether a stall time has elapsed; and controlling, in response to the stall time having elapsed, the switch of the short circuit detection circuit to disable the gate driver.

Clause 16: A power tool comprising: a housing; a motor supported by the housing; a battery pack interface configured to receive a battery pack, the battery pack including a plurality of battery cells; an inverter positioned between and electrically connected to the battery pack interface and the motor; a gate driver connected to the inverter, the gate driver configured to control a current in the inverter; a controller configured to control the gate driver; and a short circuit detection circuit configured to: monitor the current in the inverter, compare the current in the inverter to a first current threshold, compare, in response to the current in the inverter being greater than or equal to the first current threshold, the current in the inverter to a second current threshold, wherein a value of the second current threshold is based on a timer, increment, in response to the current in the inverter being greater than or equal to the second current threshold, the timer, and control, in response to the timer being greater than or equal to a timer threshold, a switch of the short circuit detection circuit to disable the gate driver.

Clause 17: The power tool of clause 16, wherein the short circuit detection circuit is further configured to: increment, in response to the increment of the timer, the second current threshold.

Clause 18: The power tool of clause 17, wherein the short circuit detection circuit is further configured to: compare, in response to the current in the inverter being greater than or equal to the first current threshold, the current in the inverter to the incremented second current threshold; and increment, in response to the current in the inverter being greater than or equal to the incremented second current threshold, the timer.

Clause 19: The power tool of any of clauses 16-18, further comprising: a rotational position detector configured to detect a position of the motor, and wherein the short circuit detection circuit is further configured to: determine, in response to the current in the inverter being greater than or equal to the second current threshold, whether the position of the motor is changing based on a signal from the rotational position detector, and increment, in response to the position of the motor not changing, the timer.

Clause 20: The power tool of any of clauses 16-19, wherein the short circuit detection circuit is further configured to: determine, in response to the current in the inverter being less than the first current threshold, whether an expected braking time has elapsed; compare, in response to the expected braking time having elapsed, the current in the inverter to the first current threshold; and control, in response to the current in the inverter being greater than or equal to the first current threshold and in response to the expected braking time having elapsed, the switch of the short circuit detection circuit to disable the gate driver.

Thus, embodiments described herein provide short circuit mitigation for a power tool. Various features and advantages are set forth in the following claims.

What is claimed is:

1. A power tool comprising:
a housing;
a motor supported by the housing;
a battery pack interface configured to receive a battery pack, the battery pack including a plurality of battery cells;
an inverter positioned between and electrically connected to the battery pack interface and the motor;
a gate driver connected to the inverter, the gate driver configured to control a current in the inverter;
a rotational position detector configured to detect a position of the motor;
a controller configured to control the gate driver; and
a short circuit detection circuit configured to:
monitor the current in the inverter,
compare the current in the inverter to a first current threshold,
determine, in response to the current in the inverter being greater than or equal to the first current threshold, whether the position of the motor is changing based on a signal from the rotational position detector, and
control, in response to the position of the motor not changing, a switch of the short circuit detection circuit to disable the gate driver.

2. The power tool of claim 1, further comprising:
an indicator configured to provide an indication of a status of the short circuit detection circuit.

3. The power tool of claim 1, wherein the rotational position detector includes a plurality of Hall effect sensors, each Hall effect sensor configured to provide a Hall effect sensor signal corresponding to a position of a rotor of the motor.

4. The power tool of claim 1, wherein the short circuit detection circuit is further configured to:
select the first current threshold based on a voltage provided by the battery pack to the battery pack interface.

5. The power tool of claim 1, wherein the short circuit detection circuit is further configured to:
adjust a value of the first current threshold based on a change in the current in the inverter.

6. The power tool of claim 1, wherein the short circuit detection circuit is further configured to:
determine whether an expected braking time has elapsed;
compare, in response to the expected braking time having elapsed, the current in the inverter to the first current threshold; and
control, in response to the current in the inverter being greater than or equal to the first current threshold and in response to the expected braking time having elapsed, the switch of the short circuit detection circuit to disable the gate driver.

7. The power tool of claim 1, wherein the short circuit detection circuit is further configured to:
determine, in response to the position of the motor not changing, whether a stall time has elapsed; and
control, in response to the stall time having elapsed, the switch of the short circuit detection circuit to disable the gate driver.

8. The power tool of claim 1, further comprising:
a trigger configured to be actuated, and wherein the short circuit detection circuit is further configured to:
detect actuation of the trigger,
drive, in response to actuation of the trigger, the motor, and
compare the current in the inverter to a first current threshold in response to the trigger being released while driving the motor.

9. The power tool of claim 8, wherein the short circuit detection circuit is further configured to:
enable the gate driver in response to actuation of the trigger and in response to the current in the inverter being less than the first current threshold.

10. A method for controlling a power tool, the method comprising:
monitoring, with a short circuit detection circuit, current in an inverter, the inverter positioned between and electrically connected to a battery pack interface and a motor;
comparing, with the short circuit detection circuit, the current in the inverter to a first current threshold;
determining, with the short circuit detection circuit and in response to the current in the inverter being greater than or equal to the first current threshold, whether a position of the motor is changing based on a signal from a rotational position detector; and
controlling, with the short circuit detection circuit and in response to the position of the motor not changing, a switch of the short circuit detection circuit to disable a gate driver, wherein the gate driver is configured to control a current in the inverter.

11. The method of claim 10, further comprising:
providing, with an indicator, an indication of a status of the short circuit detection circuit.

12. The method of claim 10, further comprising:
receiving, by the battery pack interface, a battery pack; and
selecting the first current threshold based on a voltage provided by the battery pack to the battery pack interface.

13. The method of claim 10, further comprising:
adjusting a value of the first current threshold based on a change in the current in the inverter.

14. The method of claim 10, further comprising:
determining whether an expected braking time has elapsed;
comparing, in response to the expected braking time having elapsed, the current in the inverter to the first current threshold; and
controlling, in response to the current in the inverter being greater than or equal to the first current threshold and in response to the expected braking time having elapsed, the switch of the short circuit detection circuit to disable the gate driver.

15. The method of claim 10, further comprising:
determining, in response to the position of the motor not changing, whether a stall time has elapsed; and
controlling, in response to the stall time having elapsed, the switch of the short circuit detection circuit to disable the gate driver.

16. A power tool comprising:
a housing;
a motor supported by the housing;
a battery pack interface configured to receive a battery pack, the battery pack including a plurality of battery cells;
an inverter positioned between and electrically connected to the battery pack interface and the motor;
a gate driver connected to the inverter, the gate driver configured to control a current in the inverter;
a controller configured to control the gate driver; and
a short circuit detection circuit configured to:
monitor the current in the inverter,
compare the current in the inverter to a first current threshold,
compare, in response to the current in the inverter being greater than or equal to the first current threshold, the current in the inverter to a second current threshold, wherein a value of the second current threshold is based on a timer,
increment, in response to the current in the inverter being greater than or equal to the second current threshold, the timer, and
control, in response to the timer being greater than or equal to a timer threshold, a switch of the short circuit detection circuit to disable the gate driver.

17. The power tool of claim 16, wherein the short circuit detection circuit is further configured to:
increment, in response to the increment of the timer, the second current threshold.

18. The power tool of claim 17, wherein the short circuit detection circuit is further configured to:
compare, in response to the current in the inverter being greater than or equal to the first current threshold, the current in the inverter to the incremented second current threshold; and
increment, in response to the current in the inverter being greater than or equal to the incremented second current threshold, the timer.

19. The power tool of claim 16, further comprising:
a rotational position detector configured to detect a position of the motor, and wherein the short circuit detection circuit is further configured to:
determine, in response to the current in the inverter being greater than or equal to the second current threshold, whether the position of the motor is changing based on a signal from the rotational position detector, and
increment, in response to the position of the motor not changing, the timer.

20. The power tool of claim 16, wherein the short circuit detection circuit is further configured to:
determine, in response to the current in the inverter being less than the first current threshold, whether an expected braking time has elapsed;
compare, in response to the expected braking time having elapsed, the current in the inverter to the first current threshold; and
control, in response to the current in the inverter being greater than or equal to the first current threshold and in response to the expected braking time having elapsed, the switch of the short circuit detection circuit to disable the gate driver.
